(19) United States
(12) Patent Application Publication
(10) Pub. No.: US 2007/0196952 A1
(43) Pub. Date: Aug. 23, 2007

(54) Manufacturing method of semiconductor device

(76) Inventors: Atsushi Yoshimura, Yokosuka-shi (JP); Tadanobu Okubo, Yokkaichi-shi (JP); Yasuo Tane, Yokkaichi-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/651,561

(22) Filed: Jan. 10, 2007

(30) Foreign Application Priority Data
Jan. 11, 2006 (JP) P2006-003663

(51) Int. Cl. H01L 21/00

(52) U.S. Cl. 438/108

(57) ABSTRACT

A substrate having an element mounting portion is placed on a suction stage having a suction hole. The suction hole is provided so as to suck a region excluding the element mounting portion of the substrate. Otherwise, the suction hole has a hole size of not less than 0.5 mm nor more than 1.0 mm. A fist semiconduct or substrate is sucked with a suction rubber collet with Shore A hardness of not less than 50 nor more than 70. The first semiconductor element is bonded to the element mounting portion of the substrate. A second semiconductor element having an adhesive layer with a remaining volatile content of 0.5% or less is disposed on the first semiconductor substrate. The adhesive layer is heated to a temperature in a range of not less than 120° C. nor more than 150° C. and bonded.

### CROSS-REFERENCE TO RELATED APPLICATION

This application is based upon and claims the benefit of priority from the prior Japanese Patent Application No. 2006-003663, filed on Jan. 11, 2006; the entire contents of which are incorporated herein by reference.

### BACKGROUND OF THE INVENTION

1. Field of the Invention

The present invention relates to a manufacturing method of a semiconductor device.

2. Description of the Related Art

In order to realize miniaturization, high density assembling or the like of a semiconductor device, a staked-multichip package in which a plurality of semiconductor elements are laminated and sealed in one package is in practical use. In the stacked multichip package, the plural semiconductor elements are laminated in sequence on a wiring board via an adhesive layer. Electrode pads of the respective semiconductor elements are electrically connected to connection pads of the wiring board via bonding wires.

When the plural semiconductor elements are laminated, the adhesive layer formed on a lower surface of the upper side semiconductor element is softened by heating, the softened adhesive layer is made to adhere to the lower side semiconductor element, and then the adhesive layer is thermoset to bond between the semiconductor elements. On this occasion, if many volatile ingredients (solvents or the like) remain in the adhesive layer, there is a problem that the volatile ingredient evaporates in the adhesive layer at a time of heating and that a void (hereinafter, referred to as a foam void) occurs. As the foam void occurs after the bonding, the adhesive layer becomes partly thick by a formed volume. This becomes a cause of deforming the semiconductor element. Further, this becomes a cause of hampering thermal conduction or the like between the semiconductor elements.

For the points described above, it is possible to reduce a generation amount of the foam void by decreasing a remaining volatile content of the adhesive layer. However, if the remaining volatile content is simply decreased, a viscosity of the adhesive agent becomes high and an adhesiveness to the semiconductor element is reduced. Further, in order to prevent occurrence of an insulation failure or a short-circuit due to a contact of the bonding wire of the lower side semiconductor element and the upper side semiconductor element, a thickness of the adhesive layer between the semiconductor elements is made thick to embed the bonding wire into the adhesive layer (see Japanese Patent Application Laid-open No. 2004-072009). In this case, if a viscosity of an adhesive agent is high, a deformation or a contact failure of the bonding wire becomes easy to occur.

Further, as a void occurring between the wiring board and the semiconductor element or in the adhesive layer between the plural semiconductor elements, there is an embrace void in addition to the above-described foam void. The embrace void occurs, when the semiconductor element is bonded to the wiring board or other semiconductor element, due to a deformation of the wiring board or the other semiconductor element or war page or the like of the semiconductor element to be bonded. In Japanese Patent Application Laid-open No. 2002-252254 and Japanese Patent Application Laid-open No. 2003-133707, there are described restraining inclusion (embrace) of air and discharging the included air by controlling a heating temperatures of an adhesive agent in two steps. However, this method is not able to sufficiently restrain the void due to a local deformation or the like.

### SUMMARY OF THE INVENTION

A manufacturing method of a semiconductor device according to a mode of the present invention includes: bonding a first semiconductor element having an electrode pad on a substrate having connecting portions; connecting the connecting portion of the substrate and the electrode pad of the first semiconductor element via a first bonding wire; forming an adhesive layer with a remaining volatile content of 0.5% or less on a back surface of a second semiconductor element having an electrode pad; disposing the second semiconductor element on the first semiconductor element via the adhesive layer; making the adhesive layer adhere to the first semiconductor element while heating the adhesive layer to a temperature of not less than 120° C. nor more than 150° C. to soften or melt at least a part of the adhesive layer; bonding the second semiconductor element to the first semiconductor element by thermosetting the adhesive layer made to adhere to the first semiconductor element; and connecting the connecting portion of the substrate and the electrode of the second semiconductor element via a second bonding wire.

A manufacturing method of a semiconductor device according to another mode of the present invention includes: placing a substrate having an element mounting portion and a connecting portion on a suction stage having a suction hole provided to suck a region excluding the element mounting portion of the substrate; sucking a semiconductor element having an electrode pad provided on a front surface and an adhesive layer formed on a back surface, with a suction rubber collet with Shore A hardness of not less than 50 nor more than 70; disposing the semiconductor element sucked with the suction rubber collet on the element mounting portion of the substrate held by the suction stage, via the adhesive layer; bonding the semiconductor element to the substrate by heating the adhesive layer; and connecting the connecting portion of the substrate and the electrode pad of the semiconductor element via a bonding wire.

A manufacturing method of a semiconductor device according to still another mode of the present invention includes: placing a substrate having an element mounting portion and a connecting portion on a suction stage having a suction hole with a hole size of not less than 0.5 mm nor more than 1.0 mm; sucking a semiconductor element having an electrode pad provided on a front surface and an adhesive layer formed on a back surface, with a suction rubber collet with Shore A hardness of not less than 50 nor more than 70; disposing the semiconductor element sucked with the suction rubber collet on the element mounting portion of the substrate held by the suction stage, via the adhesive layer; bonding the semiconductor element to the substrate by heating the adhesive layer; and connecting the connecting portion of the substrate and the electrode pad of the semiconductor element via a bonding wire.

### BRIEF DESCRIPTION OF THE DRAWINGS

FIG. 1 is a cross-sectional view showing a constitution of a laminated semiconductor device produced by applying a manufacturing method according to an embodiment of the present invention.

FIG. 2 is a cross-sectional view showing a modification example of the laminated semiconductor device shown in FIG. 1.

FIG. 3A and FIG. 3B are cross-sectional views showing a bonding process of a first semiconductor element in a manufacturing process of the embodiment.

FIG. 4 is a graph showing an example of a relation between a hardness of a suction rubber collet and a hole size of a suction hole of a heating stage, and an occurrence rate of an embrace void.

FIGS. 5A, FIG. 5B and FIG. 5C are cross-sectional views showing a bonding process of a second semiconductor element in the manufacturing process of the embodiment.

FIG. 6 is a graph showing an example of a relation between a remaining volatile content and an adhesive temperature of a second adhesive layer, and an occurrence rate of a foam void.

### DESCRIPTION OF THE EMBODIMENTS

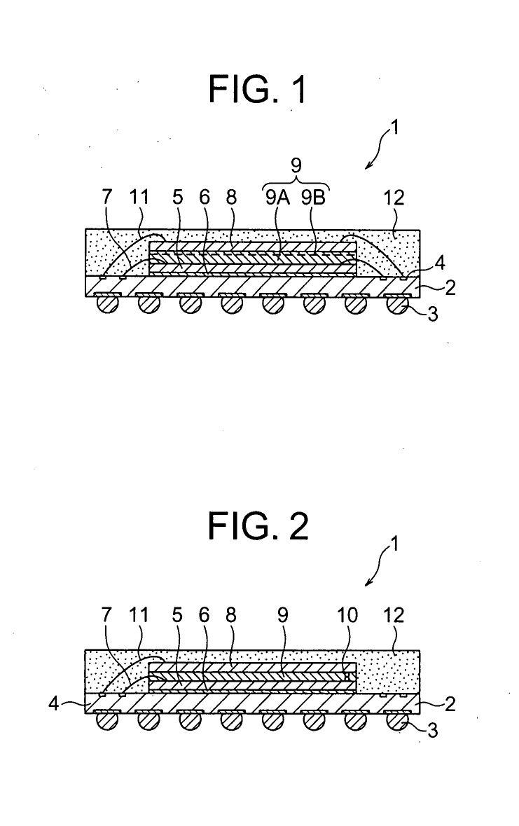

Hereinafter, a mode for implementing the present invention will be described. FIG. 1 shows a constitution of a semiconductor device of a stacked multichip structure produced by applying a manufacturing method of a semiconductor device according to an embodiment of the present invention. A laminated semiconductor device 1 shown in FIG. 1 has a substrate 2 for mounting an element. It is enough that the substrate 2 is capable of mounting the semiconductor element and has a circuit. As the substrate 2, there can be cited a wiring board in which a wiring network is formed on a surface or inside of an insulating substrate or a semiconductor substrate, a substrate such as a lead frame in which an element mounting portion and a circuit portion are integrated, or the like.

The laminated semiconductor device 1 shown in FIG. 1 includes a wiring board 2 as the substrate for mounting the element. To the substrate constituting the wiring substrate 2, a substrate made of various materials can be applied such as an insulating substrate such as a resin substrate, a ceramics substrate or a glass substrate, or a semiconductor substrate or the like. As the wiring board to which the resin substrate is applied, a general multilayer copper-clad laminate board (multilayer printed wiring board) or the like can be cited. External connection terminals 3 of solder bumps or the like are provided on a lower surface of the wiring board 2.

Connection pads 4 which are electrically connected to the external connection terminals 3 via a wiring network (not shown) are provided on an upper surface to be an element mounting surface of the wiring board 2. The connection pad 4 functions as a connecting portion and is to be a wire bonding portion. A first semiconductor element 5 is bonded to the element mounting surface (upper surface) of the wiring board 2 via a first adhesive layer 6. For the first adhesive layer 6, a general die attach material is used. A first electrode pad (not shown) provided on an upper surface of the first semiconductor element 5 is electrically connected to the connection pad 4 of the wiring board 2 via a first bonding wire 7.

A second semiconductor element 8 is bonded on the first semiconductor element 5 via a second adhesive layer 9. The second semiconductor element 8 has a shape which is the same as that of the first semiconductor element 5 or which is larger at least in a part than that of the first semiconductor element 5. The second adhesive layer 9 is to bond the first semiconductor element 5 and the second semiconductor element 8, while at least a part of the second adhesive layer 9 is softened or melted at an adhesive temperature and an end portion connected to the first semiconductor element 5 (element side end portion) of the first bonding wire 7 is embedded into the second adhesive layer 9. On this occasion, the element side end portion of the first bonding wire 7 is prevented from contacting the second semiconductor element 8 by being embedded into the second adhesive layer 9.

Further, in order to more surely prevent a contact of the element side end portion of the first bonding wire 7 with the second semiconductor element 8, it is preferable that the second adhesive layer 9 has a first resin layer 9A which is softened or melted at the adhesive temperature and a second resin layer 9B which maintains a layer shape against the adhesive temperature. The first resin layer 9A is disposed on a first semiconductor element 5 side and functions as a bonding layer of the second semiconductor element 8. The element side end portion of the first bonding wire 7 is embedded into the first resin layer 9A at a time of bonding. The second resin layer 9B is disposed on a second semiconductor element 8 side and functions as an insulating layer when the second semiconductor element 8 is bonded. The contact of the first bonding wire 7 with the second semiconductor element 8 is more surely prevented by the second resin layer 9B.

In the adhesive layer 9 of a two-layer structure, it is preferable that a thickness of the first resin layer 9A is properly set in response to a height of the first bonding wire 7. If a maximum height of the first bonding wire 7 on the first semiconductor element 5 is 60±15 μm, it is preferable that the thickness of the first resin layer 9A which is softened or melted at the adhesive temperature is 75±15 μm. It is preferable that a thickness of the second resin layer 9B which maintains the layer shape against the adhesive temperature is in a range of 5 to 15 μm. In order to satisfactorily exhibit functions of the respective resin layers 9A and 9B, it is preferable that the first resin layer 9A has a viscosity at the adhesive temperature of not less than 1 kpa·s nor more than 100 kpa·s. It is preferable that the second resin layer 9B has a viscosity at the adhesive temperature of 130 kPa·s or more.

As for the adhesive layer 9 of the two-layer structure, for example, an adhesive film of a two-layer structure is applied in advance on a back surface (adhesion surface) of the second semiconductor element 8, the adhesive film of the two-layer structure being made by laminating the first resin layer 9A made of an epoxy resin layer which is controlled to be softened or melted at the adhesive temperature and the second resin layer 9B made of a polyimide resin layer, silicon resin layer or the like which maintains the layer shape against the adhesive temperature. However, when the adhesive film of the two-layer structure of different materials is used, it is afraid that a detachment between the elements occurs after a bonding process of the second semiconductor element 8 or that a manufacturing cost for the adhesion is increased, based on difference of thermal expansion coefficients of the first resin layer 9A and the second resin layer 9B.

Thus, it is preferable that insulating resins of the same material are applied to the first and the second resin layers 9A and 9B constituting the adhesive layer 9 of the two-layer structure. As the insulating resin, a thermosetting resin such as the epoxy resin for example can be cited. When the first resin layer 9A and the second rein layer 9B are formed of the insulating resins of the same material, it is possible to make behavior (function) at the adhesive temperature different by, for example, using the same thermosetting resin compositions and making a drying temperature or a drying time in forming the first resin layer 9A and the second resin layer 9B different.

In other words, it is possible to obtain the first resin layer 9A which functions as a softened or melted layer and the second resin layer 9B which functions as an insulating layer from the insulating resins of the same material. For example, after the epoxy resin composition (stage A) is applied on a base material, this applied layer is dried at a predetermined temperature to form the second resin layer 9B in a half-cured state (stage B). Subsequently, the same epoxy resin composition (stage A) is applied again on the second resin layer 9B, and this applied layer is dried at a lower temperature than that of the temperature for forming the second resin layer 9B to form the first resin layer 9A in the half-cured state (stage B). As will be described later, the first and second resin layers 9A and 9B in the stage B are controlled to have remaining volatile contents (remaining solvent contents) of 0.5% or less respectively.

The above-described resin layers 9A, 9B of the two-layer structure are released from the base material and used as the adhesive film. It is preferable that the adhesive film of the two-layer structure is used, being applied in advance on the back surface (adhesion surface) of the second semiconductor element 8. When the adhesive film is heated at a temperature which is not less than the drying temperature of the first resin layer 9A and is lower than the drying temperature of the second resin layer 9B, the second resin layer 9B maintains the layer shape and only the first resin layer 9A is softened or melted. Therefore, by setting the adhesive temperature of the second semiconductor element 8 in a temperature range as described above, it is possible to make the second resin layer 9B function as the insulating layer and to melt or soften the first resin layer 9A.

In order to prevent the contact of the element side end portion of the first boding wire 7 with the second semiconductor element 8, a stud bump 10 made of a metal material, a resin material or the like may be formed on an electrode pad which is not used for a connection to the first semiconductor element 5 (non connection pad), as shown in FIG. 2. The stud bump 10 is effective to maintain a distance between the first semiconductor element 5 and the second semiconductor element 8. Further, by filling the non connection pad or a fuse portion with the stub bump 10, occurrence of a void due to these is restrained.

When the stud bump 10 is interposed between the first semiconductor element 5 and the second semiconductor element 8, an adhesive resin layer of a one-layer structure can be applied to the second adhesive layer 9, as shown in FIG. 2. It is also possible to use the stud bump 10 in combination with the adhesive layer 9 of the two-layer structure. Installation of the stud bump 10 may be at one location, but it is preferable that the installation is at three or more locations passing through a barycenter of the first semiconductor element 5.

As for the second semiconductor element 8 bonded on the first semiconductor element 5 via the second adhesive layer 9, a second electrode pad (not shown) provided on an upper side of the second semiconductor element 8 is electrically connected to the connection pad 4 of the wiring board 2 via a second bonding wire 11. By sealing the first and the second semiconductor elements 5 and 8 which are laminated and disposed on the wiring board 2 using a sealing resin 12 such as the epoxy resin for example, the laminated semiconductor element 1 having a stacked multichip package structure is constructed.

Though the structure in which the two semiconductor elements 5 and 8 are laminated is described in FIG. 1 and FIG. 2, the number of lamination of the semiconductor elements is not limited thereto. The number of lamination of the semiconductor elements may be three layers or more. Further, the mode of the laminated semiconductor device is not limited to the stacked multichip package described above, but a semiconductor package (TSOP or the like) using a lead frame as the element mounting board 2 can also be used.

The laminated semiconductor device 1 of the present embodiment is produced as described below. First, the first semiconductor element 5 is bonded on the wiring board 2 using the first adhesive layer 6. In a bonding process of the first semiconductor element 5, the above-described embrace void is easy to occur. Thus, a bonding process described below in which occurrence of the embrace void is restricted is applied.

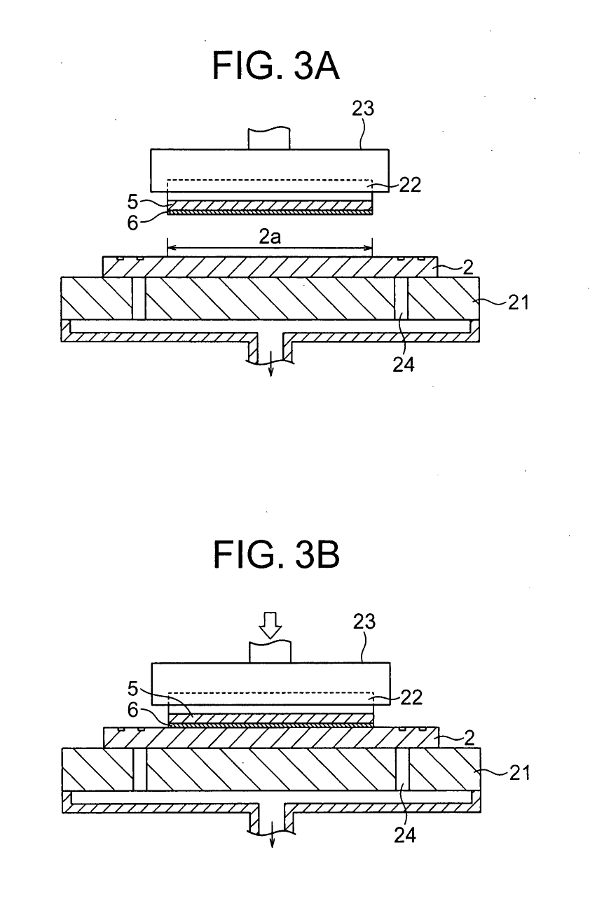

First, as shown in FIG. 3A, the wiring board 2 is placed on a suction stage (heating stage) 21 having a heating structure. On the other hand, the semiconductor element 5 is held by a suction tool 23 having a suction rubber collet 22. The heating stage 21 has a built-in heating mechanism whose depiction is omitted and has a suction hole 24 to suction-hold the wiring board 2. The suction hole 24 is connected to a suction device such as a vacuum pump, whose depiction is omitted. The suction hole 24 is provided in a part equivalent to a region excluding an element mounting portion 2a of the wiring board 2, that is, an outer peripheral region of the element mounting portion 2a.

A thickness of the wiring board 2 is as thin as 0.13 mm for example, in order to realize a thin package. When the thin wiring board 2 is suction-held by the suction hole 24, a part of the wiring board 2, a part being above the suction hole 24 is easy to be dented. If the semiconductor element 5 is disposed on a dent of the wiring board 2 caused by the suction hole 24, a void (embrace void) is easy to occur between the wiring board 2 and the semiconductor element 5. Thus, in the present embodiment, the suction hole 24 is provided so as to suck the region excluding the element mounting portion 2a of the wiring board 2.

Further, a hole size of the suction hole 24 also affects the embrace void occurring between the wiring board 2 and the semiconductor element 5. In other words, if the hole size of the suction hole 24 is too large, a load is not added to that part, and this also causes the embrace void. Thus, in the present embodiment, the hole size of the suction hole 24 is not less than 0.5 mm nor more than 1.0 mm. When the hole size of the suction hole 24 exceeds 1.0 mm, a region in which the load is not added increases, and so the embrace void becomes easy to occur. If the hole size of the suction hole 24 is less than 0.5 mm, a suction-holding force itself of the wiring board 2 is reduced, and then a holding state of the wiring board 2 becomes unstable.

As for the heating stage 21 to suction-hold the wiring board 2, the embrace void occurring between the wiring board 2 and the semiconductor element 5 is restrained by proving the suction hole 24 in the part equivalent to the region excluding the element mounting portion 2a of the wiring board 2 or making the hole size of the suction hole 24 be in a range from 0.5 to 1.0 mm. A forming position of the suction hole 24 (region excluding the element mounting portion 2a) and the hole size may be simultaneously satisfied. However, if a warp of the wiring board 2 is minor or if the suction hole 24 is not disposed directly under the semiconductor element 5, the hole size of the suction hole 24 is not constrained. Control of the forming position or the hole size of the suction hole 24 is effective, especially when a thickness of the wiring board 2 is 1 mm or less, or further, 0.2 mm or less. It is preferable that the thickness of the wiring board 2 is 0.05 mm or more in terms of practicability.

Further, a state of the semiconductor element 5 affects occurrence of the embrace void. In the present embodiment, a hardness of the suction rubber collet 22 to suction-hold the semiconductor element 5 is not less than 50 nor more than 70 in Shore A hardness. When the semiconductor element 5 as thin as 60 μm in thickness is held by the suction rubber collet 22, a deformation such as a warp is easy to occur. On this occasion, if the suction rubber collet 22 is too hard, the warp of the semiconductor element 5 cannot be absorbed when the semiconductor element 5 is pressed on the wiring board 2. This also causes the embrace void.

When the Shore A hardness of the suction rubber collet 22 exceeds 70, the warp of the semiconductor substrate 5 cannot be absorbed when the semiconductor element 5 is pressed on the wiring board 2, and the pressure for making the suction rubber collet 22 flat is needed to about 50 N, and so the embrace void becomes easy to occur in response to the influence of the suction hole 24. When the Shore A hardness of the suction rubber collet 22 is less than 50, the suction rubber collet 22 is too soft, and so a pressing force applied to the semiconductor element 5 is also absorbed. This becomes a cause of a local connection failure of the semiconductor element 5. Also hereby, the void becomes easy to occur between the wiring board 2 and the semiconductor element 5. The control of the hardness of the suction rubber collet 22 is effective, especially when the thickness of the semiconductor element 5 is 150 μm or less, or further, 100 μm or less. It is preferable that the thickness of the semiconductor element 5 is 5 μm or more in terms of practicability.

On the back surface (lower surface) of the semiconductor element 5 which is held by the suction rubber collet 22, the adhesive layer 6 is formed in advance. As shown in FIG. 3B, by heating the adhesive layer 6 to a predetermined temperature while the semiconductor element 5 is pressed via the adhesive layer 6 on the element mounting portion 2a of the wiring board 2 held by the heating stage 21, the adhesive layer 6 is thermoset so that the semiconductor element 5 is bonded to the wiring board 2. A bonding process (heating or pressing) itself of the semiconductor element 5 can be performed in the same method as a conventional method in which a die attach film or the like is used.

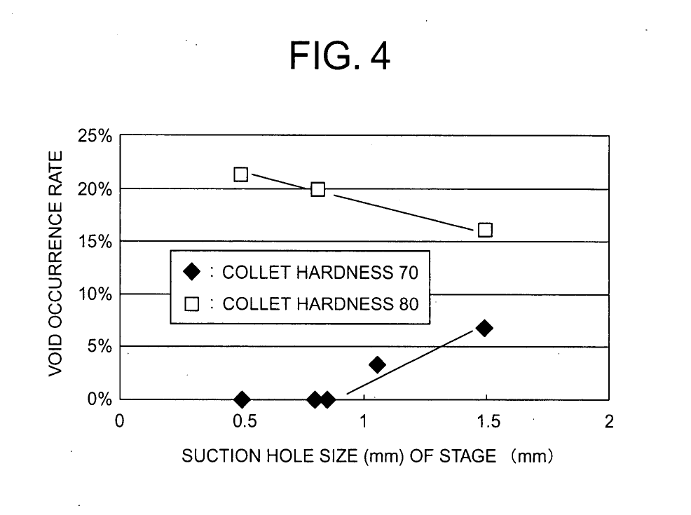

FIG. 4 shows an example of a relation between a Shore A hardness of a suction rubber collet 22 and a hole size of a suction hole 24 of a heating stage 21, and an occurrence rate of an embrace void. Here, a wiring board 2 of 0.13 mm in thickness and a semiconductor element (Si chip) 5 of 60 μm in thickness are used, and the wiring board 2 and the semiconductor element 5 are bonded by an adhesive layer 6. The suction hole 24 of the heating stage 21 is provided in a region excluding an element mounting region 2a of the wiring board 2. It is investigated whether the embrace void occurs or not between the wiring board 2 and the semiconductor element 5 on this occasion, as the void occurrence rate.

As is obvious from FIG. 4, it is found that the occurrence rate of the embrace void drastically increases when the Shore A hardness of the suction rubber collet 22 exceeds 70. Incidentally, though a case that the Shore A hardness of the suction rubber collet 22 is less than 50 is not shown in FIG. 4, it is verified that a connection failure of the semiconductor element 5 occurs. Further, it is found that the occurrence rate of the embrace void increases when the hole size of the suction hole 24 exceeds 1.0 mm even if the Shore A hardness of the suction rubber collet 22 is 70 or less. Incidentally, it is revealed that a suction failure of the semiconductor element 5 occurs when the hole size of the suction hole 24 is less than 0.5 mm and such a hole size is inferior in practicability.

In the present embodiment, as a stage to hold the wiring board 2, there is applied the heating stage 21 on which the suction hole 24 is provided on the part corresponding to the region excluding the element mounting portion 2a of the wiring board 2 or in which the hole size of the suction hole 24 is not less than 0.5 mm nor more than 1.0 mm. Also, as a suction collet to hold the semiconductor element 5, the suction rubber collet 22 having the Shore A hardness of not less than 50 nor more than 70 is used. The heating stage 21 may be the heating stage satisfying both conditions of a disposed position and the hole size of the suction hole 24. Thereby, occurrence of the embrace void between the wiring board 2 and the semiconductor element 5 can be restrained.

By restraining the embrace void occurring between the wiring board 2 and the semiconductor element 5, it becomes possible to enhance a bonding quality or a bonding yield of the first semiconductor element 5. Incidentally, the embrace void occurs not only in the laminated semiconductor device but also in a semiconductor device of a single-layer structure (semiconductor device mounting a single semiconductor element on a substrate). A combination of control of the disposed position or the hole size of the suction hole 24 and control of the hardness of the suction rubber collet 22 is also applicable to the semiconductor device of the single-layer structure and can enhance a bonding quality or a bonding yield of the semiconductor device of the single-layer structure.

Next, a wire bonding process is performed to the first semiconductor element 5, so that the connection pad 4 of the wiring board 2 and the electrode pad of the first semiconductor element 5 are electrically connected by the first bonding wire 7. The wire bonding process of the first semiconductor element 5 is performed in the same way as conventionally performed. Subsequently, the second semiconductor element 8 is bonded on the first semiconductor element 5 via the second adhesive layer 9. In a bonding process of the second semiconductor element 8, the above-described foam void is easy to occur.

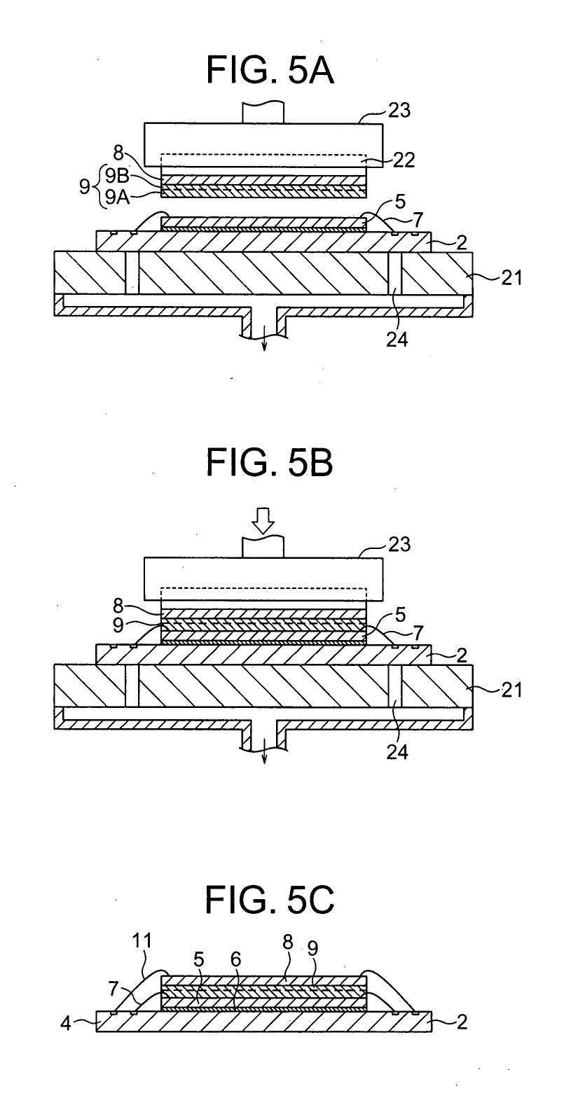

In particular, if a part (element side end portion) of the first bonding wire 7 is embedded into the second adhesive layer 9, a comparatively thick adhesive layer 9 is used and so the foam void becomes easy to occur. Thus, a bonding process described below in which occurrence of the foam void is restrained is applied. As shown in FIG. 5A, the wiring board 2 on which the first semiconductor element 5 is bonded is placed on a heating stage 21. On the other hand, the second semiconductor element 8 is held by a suction tool 23 having a suction rubber collet 22.

It is preferable that the heating stage 21 or the suction rubber collet 22 has the same structure as that used in bonding of the first semiconductor element 5 described above, but is not limited thereto. At a time of bonding of the second semiconductor element 8, an embrace void is hard to occur compared to at a time of bonding of the first semiconductor element 5, since a deformation of the substrate 2 or the second semiconductor element 8 is absorbed by a first adhesive layer 6 or a second adhesive layer (for example adhesive layer of a two-layer structure) 9. Therefore, the heating stage 21 or the suction rubber collet 22 is not limited to the structure described above.

The second adhesive layer 9 is formed in advance on the back surface (lower surface) of the second semiconductor element 8. The second adhesive layer 9 is formed by attaching a half-cured adhesive film (film of stage B) to the back surface of the second semiconductor element 8 or applying an adhesive composition on the back surface of the second semiconductor element 8. If the adhesive layer of the two-layer structure is applied as the second adhesive layer 9, the adhesive film of the two-layer structure produced in the above-described method is attached in advance on a back surface side of the second semiconductor element 8.

In a forming process of the second adhesive layer 9, a drying temperature or a drying time (heat treating temperature or heat treating time for conversion to the stage B) of the adhesive composition (resin composition of stage A) is controlled such that a remaining amount of a volatile content (remaining volatile content) due to a solvent or the like in the adhesive composition is 0.5% or less (mass ratio). If the remaining volatile content of the second adhesive layer 9 exceeds 0.5%, the foam void becomes easy to occur at a time of thermosetting after the second adhesive layer 9 is made to adhere to the first semiconductor element 5, because of the volatile content generated from the second adhesive layer 9. Occurrence of the foam void can be restrained by using the second adhesive layer 9 whose remaining volatile content is 0.5% or less. In a case of the adhesive layer 9 of the two-layer structure, a total amount of the remaining volatile content is made to be 0.5% or less.

It is more preferable that the remaining volatile content of the second adhesive layer 9 is 0.2% or less, though it depends on a heating temperature described later of the second adhesive layer 9. By making the remaining volatile content of the second adhesive layer 9 be 0.2% or less, occurrence of the foam void can be more surely restrained. Further, also in a case that the heating temperature of the second adhesive layer 9 is made higher in a certain extent, occurrence of the foam void can be restrained. In the case that the element side end portion of the first bonding wire 7 is embedded into the second adhesive layer 9, embedding of the first bonding wire 7 is enhanced by raising the heating temperature and reducing a viscosity of the second adhesive layer 9.

As shown in FIG. 5B, the second semiconductor element 8 having the second adhesive layer 9 is pressed against the first semiconductor element 5, so that the second adhesive layer 9 is made to adhere to the first semiconductor element 5. The second adhesive layer 9 is heated by radiant heat from the heating stage 21 or the first semiconductor element 5 heated thereby. A heating mechanism may be housed in a suction tool 23 having the suction rubber collet 22 and the second semiconductor element 8 and the second adhesive layer 9 may be directly heated by this heating mechanism.

In order to restrain occurrence of the foam void, at least a part of the second adhesive layer 9 is softened or melted by applying heat such that a temperature of the second adhesive layer 9 becomes not less than 120° C. nor more than 150° C. Since the viscosity of the second adhesive layer 9 becomes high by making the remaining volatile content be 0.5% or less, the second adhesive layer 9 cannot be sufficiently adhered to the first semiconductor element 5 if the heating temperature at bonding (adhesive temperature) is too low. In other words, if the adhesive temperature of the second adhesive layer 9 is less than 120° C., an adhesiveness to the first semiconductor element 5 deteriorates.

Further, since the first bonding wire 7 is connected to the first semiconductor element 5, it is necessary that the first bonding wire 7 is embedded into the second adhesive layer 9 at the time of bonding. If the adhesive temperature of the second adhesive layer 9 it too low, a softened state of the second adhesive layer 9 becomes insufficient, and so a deformation or a contact failure becomes easy to occur to the first bonding wire 7. By making the adhesive temperature of the second adhesive layer 9 be 120° C. or more, the first bonding wire 7 can be satisfactorily embedded into the second adhesive layer 9. When the adhesive layer of the two-layer structure is applied to the second adhesive layer 9, the first bonding wire 7 is embedded into the first resin layer 9A.

If the adhesive temperature of the second adhesive layer 9 is too high, the foam void is easy to occur at the time of bonding even in a second adhesive layer 9 with a reduced remaining volatile content. Thus, the adhesive temperature of the second adhesive layer 9 is made to be 150° C. or less. In a case that a second adhesive layer 9 with a remaining volatile content of 0.2% or less is used, the occurrence rate of the foam void drastically increases when the adhesive temperature of the second adhesive layer 9 exceeds 150° C. In a case that a second adhesive layer 9 with a remaining volatile content of 0.5% or les is used, the occurrence rate of the foam void drastically increases when the adhesive temperature of the second adhesive layer 9 exceeds 140° C. The adhesive temperature of the second adhesive layer 9 is made to be 150° C. or less, or further, 140° C. or less, in response to the remaining volatile content.

After the first bonding wire 7 is embedded into the second adhesive layer 9 heated to the above-described temperature and the second adhesive layer 9 is made to adhere to the first semiconductor element 5, a moderate pressure is applied to the second semiconductor element 8 while the heating of the second adhesive layer 9 is continued. Hereby, the second adhesive layer 9 is thermoset so that the second semiconductor element 8 is bonded to the first semiconductor element 5. By setting the heating temperature of the second adhesive layer 9 with the reduced remaining volatile content to the temperature corresponding to the remaining volatile content, an adhesiveness of the second adhesive layer 9 against the first semiconductor element 5 or an embedding property of the first bonding wire 7 is maintained satisfactory, and occurrence of the foam void between the first semiconductor element 5 and the second semiconductor element 8 can be restrained.

It is preferable that a thickness of the second adhesive layer 9 is 26 μm or more, or further, 70 μm or more in order to embed the first bonding wire 7. It is preferable that the thickness of the second adhesive layer 7 is 150 μm or less interims of practicability. By controlling the remaining volatile content and the heating temperature of the second adhesive layer 9 having such a thickness, occurrence of the foam void can be restrained while the embedding property of the first bonding wire 7 is maintained satisfactory. In the second adhesive layer 9 with the thickness of 26 μm, or further, 70 μm, even if a proportion of the remaining volatile content is the same, the foam void is easy to occur since a total amount of the remaining volatile content increases. Even in such a case, occurrence of the foam void can be effectively restrained by controlling the remaining volatile content and the heating temperature of the second adhesive layer 9.

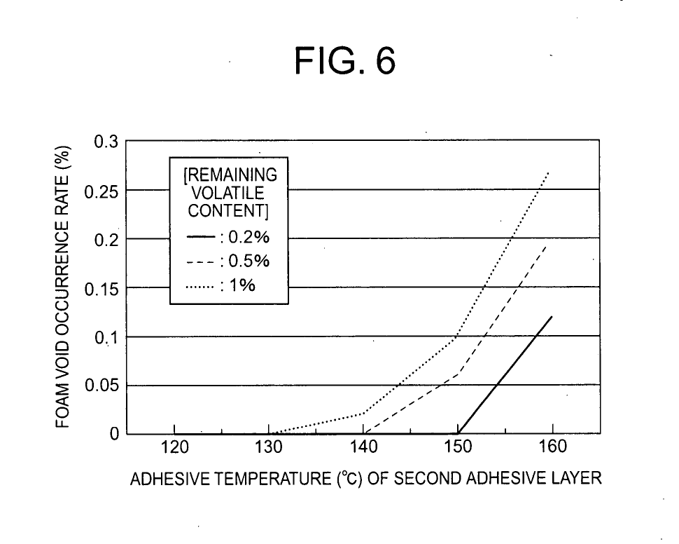

FIG. 6 shows an example of a relation between a remaining volatile content and an adhesive temperature of a second adhesive layer 9 and an occurrence rate of a foam void. Here, an adhesive layer of a two-layer structure (epoxy resin layer of a two-layer structure) 9 is used to bond a second semiconductor element (Si chip) 8 with a thickness of 60 μm on a first semiconductor element 5. It is investigated whether the foam void occurs or not between the first semiconductor element 5 and the second semiconductor element 8 at that time as the foam void occurrence rate.

As is obvious from FIG. 6, when the remaining volatile content of the second adhesive layer 9 exceeds 0.5%, the occurrence rate of the foam void obviously increases. Further, in a second adhesive layer 9 with a remaining volatile content of 0.2%, the occurrence rate of the foam void increases when an adhesive temperature exceeds 150° C. In a second adhesive layer 9 with a remaining volatile content of 0.5%, the occurrence rate of the foam void increases when the adhesive temperature exceeds 140° C. Therefore, when the remaining volatile content of the second adhesive layer 9 is 0.2% or less, it is preferable that the adhesive temperature is not less than 120° C. nor more than 150° C. When the remaining volatile content of the second adhesive layer 9 is 0.5% or less, it is preferable that the adhesive temperature is not less than 120° C. nor more than 140° C.

It is found that the occurrence rate of the foam void can be drastically reduced by making the adhesive temperature of the second adhesive layer 9 with the remaining volatile content of 0.2% or less be 150° C. or less or making the adhesive temperature of the second adhesive layer 9 with the remaining volatile content of 0.5% or less be 140° C. or less. When the second adhesive layer 9 with the remaining volatile content of 0.5% or less, it is preferable that the heating of the second adhesive layer 9 is step heating (step cure). It is verified that an occurrence rate of a deformation or a contact failure of the first bonding wire 7 increases regardless of an amount of the remaining volatile content when the adhesive temperature of the second adhesive layer 9 is less than 120° C.

Subsequently, as shown in FIG. 5C, a wire bonding process is performed to the second semiconductor element 8 bonded on the first semiconductor element 5, and a connection pad 4 of the wiring board 2 and an electrode pad of the second semiconductor element 8 is electrically connected by a second bonding wire 11. Further, by sealing the first and the second semiconductor elements 5 and 8 with a sealing resin 12, the laminated semiconductor device 1 shown in FIG. 1 can be obtained. Incidentally, in a case that three or more semiconductor elements are laminated, the same bonding step as the above-described step for the second semiconductor element 8 is performed repeatedly.

In the present embodiment, since the remaining volatile content of the second adhesive layer 9 is decreased and the adhesive temperature of the second adhesive layer 9 is controlled, occurrence of the foam void between the first semiconductor element 5 and the second semiconductor element 8 can be restrained. This greatly contributes to improvement of a bonding quality or a bonding yield of the second semiconductor element 8. Further, since occurrence of the embrace void between the substrate 2 and the first semiconductor element 5 can be restrained by applying the above-described bonding process for the first semiconductor element 5, it becomes possible to manufacture with a good yield the laminated semiconductor device 1 which is superior in quality, reliability or the like.

It should be noted that the manufacturing method of the present invention is not limited to the respective embodiments described above, but can be applied to various laminated semiconductor devices on which a plurality of semiconductor elements are mounted and laminated. A manufacturing method of such a laminated semiconductor device is included in the present invention. Also, the embodiment of the present invention may be expanded or modified within a scope of technical conception of the present invention, and the expanded and/or modified embodiments are also included in the technical scope of the present invention.

What is claimed is:

1. A manufacturing method of a semiconductor device, comprising:
bonding a first semiconductor element having an electrode pad on a substrate having connecting portions;
connecting the connecting portion of the substrate and the electrode pad of the first semiconductor element via a first bonding wire;
forming an adhesive layer with a remaining volatile content of 0.5% or less on a back surface of a second semiconductor element having an electrode pad;
disposing the second semiconductor element on the first semiconductor element via the adhesive layer;
making the adhesive layer adhere to the first semiconductor element while heating the adhesive layer to a temperature of not less than 120° C. nor more than 150° C. to soften or melt at least a part of the adhesive layer;
bonding the second semiconductor element to the first semiconductor element by thermosetting the adhesive layer made to adhere to the first semiconductor element; and
connecting the connecting portion of the substrate and the electrode of the second semiconductor element via a second bonding wire.

2. The manufacturing method of the semiconductor device as set forth in claim 1,
wherein the remaining volatile content of the adhesive layer is 0.2% or less and the heating temperature of the adhesive layer is not less than 120° C. nor more than 150° C.

3. The manufacturing method of the semiconductor device as set forth in claim 1,
wherein the remaining volatile content of the adhesive layer is 0.5% or less and the heating temperature of the adhesive layer is not less than 120° C. nor more than 140° C.

4. The manufacturing method of the semiconductor device as set forth in claim 1,
wherein the second semiconductor element is bonded to the first semiconductor element, while a end portion connected to the first semiconductor element of the first bonding wire is embedded into the adhesive layer.

5. The manufacturing method of the semiconductor device as set forth in claim 1,
wherein the adhesive layer comprises a first resin layer disposed on the first semiconductor element side and softened or melted at the heating temperature, and a second resin layer disposed on the second semiconductor element side and maintaining a layer shape against the heating temperature.

6. The manufacturing method of the semiconductor device as set forth in claim 5,
wherein a end portion connected to the first semiconductor element of the first bonding wire is embedded into the first resin layer of the adhesive layer.

7. The manufacturing method of the semiconductor device as set forth in claim 1,
wherein the adhesive layer has a thickness of 26 μm or more.

8. A manufacturing method of a semiconductor device, comprising:
placing a substrate having an element mounting portion and a connecting portion on a suction stage having a suction hole provided to suck a region excluding the element mounting portion of the substrate;
sucking a semiconductor element having an electrode pad provided on a front surface and an adhesive layer formed on a back surface, with a suction rubber collet with Shore A hardness of not less than 50 nor more than 70;
disposing the semiconductor element sucked with the suction rubber collet on the element mounting portion of the substrate held by the suction stage, via the adhesive layer;
bonding the semiconductor element to the substrate by heating the adhesive layer; and
connecting the connecting portion of the substrate and the electrode pad of the semiconductor element via a bonding wire.

9. The manufacturing method of the semiconductor device as set forth in claim 8,
wherein the substrate has a thickness of 1 mm or less.

10. The manufacturing method of the semiconductor device as set forth in claim 8,
wherein the semiconductor element has a thickness of 150 μm or less.

11. The manufacturing method of the semiconductor device as set forth in claim 8,
wherein the suction hole has a hole size of not less than 0.5 mm nor more than 1.0 mm.

12. The manufacturing method of the semiconductor device as set forth in claim 8, further comprising:
forming a second adhesive layer on a back surface of a second semiconductor element having an electrode pad;
disposing the second adhesive layer on the semiconductor element being a first semiconductor element via the second adhesive layer;
making the second adhesive layer adhere to the first semiconductor element while heating the second adhesive layer to soften or melt at least a part of the second adhesive layer;
bonding the second semiconductor element to the first semiconductor element by thermosetting the second adhesive layer made to adhere to the first semiconductor element; and
connecting the connecting portion of the substrate and the electrode pad of the second semiconductor element via a second bonding wire.

13. The manufacturing method of the semiconductor device as set forth in claim 12,
wherein a remaining volatile content of the second adhesive layer is 0.5% or less and a heating temperature of the second adhesive layer is not less than 120° C. nor more than 150° C.

14. The manufacturing method of the semiconductor device as set forth in claim 12,
wherein the second semiconductor element is bonded to the first semiconductor element, while a end portion connected to the first semiconductor element of the bonding wire being a first bonding wire is embedded into the second adhesive layer.

15. A manufacturing method of a semiconductor device, comprising:
placing a substrate having an element mounting portion and a connecting portion on a suction stage having a suction hole with a hole size of not less than 0.5 mm nor more than 1.0 mm;
sucking a semiconductor element having an electrode pad provided on a front surface and an adhesive layer formed on a back surface, with a suction rubber collet with Shore A hardness of not less than 50 nor more than 70;
disposing the semiconductor element sucked with the suction rubber collet on the element mounting portion of the substrate suction-held by the suction stage, via the adhesive layer;
bonding the semiconductor element to the substrate by heating the adhesive layer; and
connecting the connecting portion of the substrate and the electrode pad of the semiconductor element via a bonding wire.

16. The manufacturing method of the semiconductor device as set forth in claim 15,
wherein the substrate has a thickness of 1 mm or less.

17. The manufacturing method of the semiconductor device as set forth in claim 15,
wherein the semiconductor element has a thickness of 150 μm or less.

18. The manufacturing method of the semiconductor device as set forth in claim 15, further comprising:
forming a second adhesive layer on a back surface of a second semiconductor element having an electrode pad;
disposing the second semiconductor element on the semiconductor element being a first semiconductor element via the second adhesive layer;
making the second adhesive layer adhere to the first semiconductor element while heating the second adhesive layer to soften or melt at least a part of the second adhesive layer;
bonding the second semiconductor element to the first semiconductor element by thermosetting the second adhesive layer made to adhere to the first semiconductor element; and
connecting the connecting portion of the substrate and the electrode pad of the second semiconductor element via a second bonding wire.

19. The manufacturing method of the semiconductor device as set forth in claim 18,
wherein a remaining volatile content of the second adhesive layer is 0.5% or less and a heating temperature of the second adhesive layer is not less than 120° C. nor more than 150° C.

20. The manufacturing method of the semiconductor device as set forth in claim 18,
wherein the second semiconductor element is bonded to the first semiconductor element, while a end portion connected to the first semiconductor element of the bonding wire being a first bonding wire is embedded into the second adhesive layer.
